(19) United States
(12) Patent Application Publication
(10) Pub. No.: US 2013/0233379 A1
(43) Pub. Date: Sep. 12, 2013

(54) PATTERNED ALUMINUM BACK CONTACTS FOR REAR PASSIVATION

(71) Applicants: David Tanner, San Jose, CA (US); Prabhat Kumar, Fremont, CA (US)

(72) Inventors: David Tanner, San Jose, CA (US); Prabhat Kumar, Fremont, CA (US)

(21) Appl. No.: 13/784,043

(22) Filed: Mar. 4, 2013

Related U.S. Application Data
(60) Provisional application No. 61/607,465, filed on Mar. 6, 2012.

(51) Int. Cl. H01L 31/18; H01L 31/0224

(52) U.S. Cl. CPC H01L 31/1868; H01L 31/022433
USPC 136/256; 438/71

(57) ABSTRACT

Embodiments of the invention generally relate to solar cells having reduced carrier recombination and methods of forming the same. The solar cells have eutectic local contacts and passivation layers which reduce recombination by facilitating formation of a back surface field (BSF). A patterned aluminum back contact is disposed on the passivation layer for removing current form the solar cell. The patterned back contact reduces the cost-per-watt of the solar cell by using less material than a full-surface back contact. The methods of forming the solar cells include depositing a passivation layer including aluminum oxide and silicon nitride on a back surface of a solar cell, and then forming openings through the passivation layer. A patterned aluminum back contact is disposed on the passivation layer over the holes, and thermally processed to form a silicon-aluminum eutectic within the openings.

### CROSS-REFERENCE TO RELATED APPLICATIONS

This application claims benefit of U.S. Provisional Patent Application Ser. No. 61/607,465, filed Mar. 6, 2012, which is herein incorporated by reference.

### BACKGROUND OF THE INVENTION

1. Field of the Invention

Embodiments of the invention generally relate to solar cells having reduced carrier recombination, and thus higher efficiency, and methods of forming the same.

2. Description of the Related Art

Solar cells generate energy via the photovoltaic effect which is enabled by exposing the solar cells to radiation, such as sunlight. Illumination of a solar cell with radiation creates an electric current as excited electrons and the holes move in different directions through the radiated cell. The electric current may be extracted from the solar cell and used as energy.

However, if the electrons and the holes recombine prior to the extraction of current, energy dissipates from the solar cell in the form of heat. The recombination of the electrons and the holes reduces the amount of usable power generated by the solar cell, and thus, the efficiency of the solar cell is likewise reduced.

Therefore, there is a need for a solar cell with reduced carrier recombination and increased efficiency.

### SUMMARY OF THE INVENTION

Embodiments of the invention generally relate to solar cells having reduced carrier recombination and methods of forming the same. The solar cells have eutectic local contacts and passivation layers which reduce recombination by facilitating formation of a back surface field (BSF). A patterned aluminum back contact is disposed on the passivation layer for removing current form the solar cell. The patterned back contact reduces the cost-per-watt of the solar cell by using less material than a full-surface back contact. The methods of forming the solar cells include depositing a passivation layer including aluminum oxide and silicon nitride on a back surface of a solar cell, and then forming openings through the passivation layer. A patterned aluminum back contact is disposed on the passivation layer over the holes, and thermally processed to form a silicon-aluminum eutectic within the openings.

In one embodiment, a solar cell is disclosed. The solar cell comprises a substrate and a front contact disposed on a light-receiving surface of the substrate. A passivation layer is disposed on a non-light-receiving surface. The passivation layer on the non-light-receiving surface has a plurality of openings therethrough and includes a first sub-layer of aluminum oxide and a second sub-layer of silicon nitride. A back contact comprising aluminum and having a grid-like shape is disposed on the non-light-receiving surface passivation layer. The solar also includes a plurality of local contacts formed at the interface of the substrate and the back contact disposed within the openings. The plurality of local contacts comprise a silicon-aluminum eutectic alloy.

In another embodiment, a method of forming a solar cell is disclosed. The method comprises disposing a passivation layer on a non-light receiving surface of a substrate. The passivation layer comprises a first sub-layer of aluminum oxide, and a second sub-layer of silicon nitride disposed on the first sub-layer of aluminum oxide. A plurality of openings are then formed through the passivation layer, and an aluminum paste is disposed over the passivation layer in grid-like pattern including the openings. The substrate and the aluminum paste disposed thereon are then heated to a temperature above a silicon-aluminum eutectic point.

In another embodiment, a method of forming a solar cell is disclosed. The method comprises disposing a passivation layer on a non-light receiving surface of a substrate. The passivation layer comprises a first sub-layer of aluminum oxide having a thickness of about 20 nanometers or more, and a second sub-layer of silicon nitride having a thickness within a range of about 20 nanometers to about 150 nanometers. A plurality of openings are then formed through the passivation layer using a laser, and an aluminum paste is disposed over the passivation layer in grid-like pattern. The aluminum paste is disposed over and within the openings. The substrate is then thermally processed, which includes heating the substrate and the aluminum paste thereon to a temperature above a silicon-aluminum eutectic point, and allowing the substrate to cool.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of a solar cell according to one embodiment of the invention.

FIG. 2 is a schematic plan view of a back surface of a solar cell according to one embodiment of the invention.

FIG. 3 is flow diagram illustrating a method of forming a solar cell according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention generally relate to solar cells having reduced carrier recombination and methods of forming the same. The solar cells have eutectic local contacts and passivation layers which reduce recombination by facilitating formation of a back surface field (BSF). A patterned aluminum back contact is disposed on the passivation layer for removing current form the solar cell. The patterned back contact reduces the cost-per-watt of the solar cell by using less material than a full-surface back contact. The methods of forming the solar cells include depositing a passivation layer including aluminum oxide and silicon nitride on a back surface of a solar cell, and then forming openings through the passivation layer. A patterned aluminum back contact is disposed on the passivation layer over the holes, and thermally processed to form a silicon-aluminum eutectic within the openings.

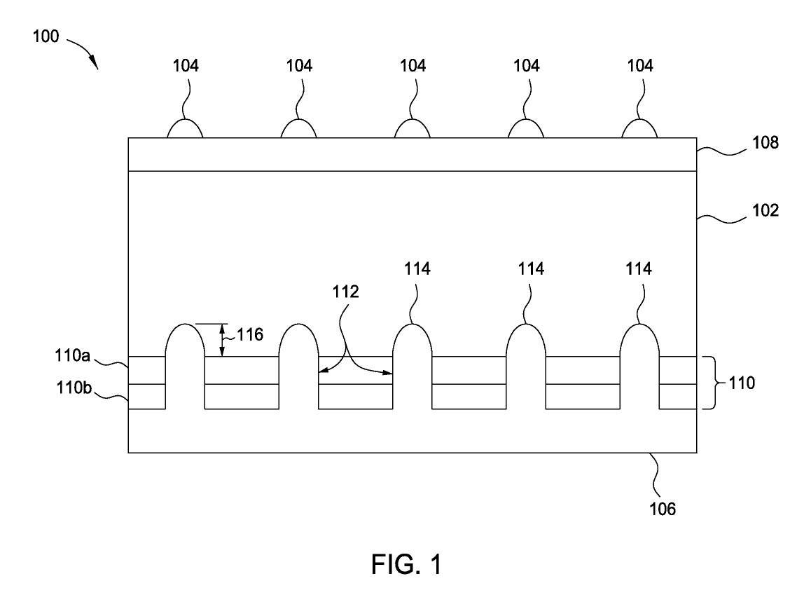

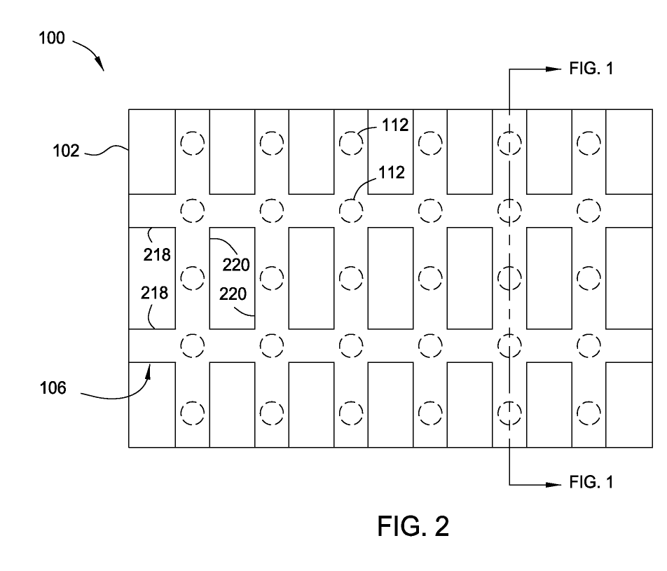

FIG. 1 is a schematic sectional view of a solar cell 100 according to one embodiment of the invention. The solar cell 100 includes a semiconductor substrate 102, such as a silicon substrate (e.g., monocrystalline silicon or multicrystalline silicon). In one example, the semiconductor substrate 102 may be a p-type crystalline silicon substrate. The solar cell 100 includes a front surface contact 104 disposed on a light-receiving surface of the solar cell 100 and a back surface contact 106 disposed on the non-light-receiving surface of the solar cell 100. The front contact 104 and the back contact 106 are arranged in grid-like patterns including one or more busbars and a plurality of fingers coupled therewith and arranged perpendicularly thereto (as shown in FIG. 2). The front contact 104 includes silver and aluminum, and the back contact 106 includes aluminum.

The solar cell 100 also includes an n-type region 108 adjacent to the front contact 104, and a passivation layer 110 between the back contact 106 and the substrate 102. The passivation layer 110, in combination with local contacts 114 (which are formed from the back contact material), facilitates formation of a back surface field in a region around the local contacts 114 which repels minority charge carriers. The minority charge carriers are repelled due to the presence of a high concentration of a p-type dopant, such as aluminum, within the formed local contacts 114. The repelling of minority charge carriers reduces carrier recombination near the non-light-receiving surface of the solar cell 100. In one configuration, the passivation layer 110 includes two sub-layers, an aluminum oxide layer 110a and a silicon nitride layer 110b. The aluminum oxide layer 110a passivates the rear surface of the solar cell 100 and facilitates formation of local contacts 114, while the silicon nitride layer 110b serves as a protective coating over the aluminum oxide layer. The silicon nitride layer 110b protects the aluminum oxide layer 110a from materials utilized to form the back contact 106 during thermal processing steps (e.g., firing steps). Some materials used to form the back contact 106 may adversely affect the aluminum oxide layer 110a, for example, by dissolving the aluminum oxide layer 110a, thereby degrading the passivation qualities of the aluminum oxide layer 110a. The aluminum oxide layer 110a generally has a thickness of about 20 nanometers or more, for example, about 50 nanometers. The silicon nitride layer 110b generally has a thickness within a range of about 20 nanometers to about 100 nanometers, such as about 50 nanometers to about 80 nanometers. In one example, the total thickness of the passivation layer 110 is about 100 nanometers.

The passivation layer 110 includes a plurality of openings 112 formed therein to allow electrical communication between the substrate 102 and the back contact 106. The openings have a diameter within a range of about 20 microns to about 200 microns, and a pitch of about 100 microns to about 1000 microns. The back contact 106 extends into the openings 112 and is thermally processed to form local contacts 114. The formed local contacts 114 are a eutectic alloy material formed from the substrate 102 and the back contact 106. In one example, the eutectic material is an aluminum/silicon eutectic alloy. In such an example, the local contacts may contain about 12 percent (%) aluminum in silicon near the substrate 102, and about 1% silicon in aluminum near the back contact 106. The local contacts 114 may extend past the passivation layer 110 a distance 116, which is within a range of about 5 microns to about 60 microns. The distance 116 is generally dependent on the diameter of the openings 112, as well as the length of time and temperature of the heating process used to form the eutectic alloy material within the local contacts 114.

FIG. 1 describes one embodiment of a solar cell 100; however, other embodiments are also contemplated. For example, it is contemplated that other metals may be utilized to form either the front contact 104 or the back contact 106, including gold, silver, aluminum, platinum, or combinations thereof. In another embodiment, it is contemplated that the silicon nitride layer 110b may be eliminated. In such an embodiment, the aluminum oxide layer 110a may have a thickness of about 100 nanometers. In yet another embodiment, it is contemplated that the diameter and pitch of the openings 112 may be varied to provide the desired level of electrical connection by increasing the contact area between the substrate 102 and the back contact 106. Additionally, the distance 116 can be reduced by increasing the contact area between the substrate 102 and the back contact 106 (e.g., the diameter of the local contacts 114).

FIG. 2 is a schematic plan view of a back surface (e.g., non-light-receiving surface) of a solar cell 100 according to one embodiment of the invention. The solar cell 100 includes a back contact 106 including a plurality of busbars 218 and a plurality of fingers 220 in electrical communication therewith. A plurality of openings 112 (shown in phantom) are disposed through the passivation layer 110 and beneath the back contact 106 to facilitate electrical connection between the back contact 106 and the substrate 102 of the solar cell 100. It is contemplated that the size and pitch of the openings 112, as well as the number and spacing of the busbars 218 and the fingers 220 may be varied to provide the desired electric current flow. The back contact 106 generally has a thickness within a range of about 15 microns to about 35 microns. In one example, to reduce the manufacturing cost of the solar cell, the back contact 106 is configured to cover about 50% or less of the surface area of the non-light-receiving side of the solar cell 100. The back contact 106 generally has a sheet resistance within a range of about 8 milliohms-per-square to about 18 milliohms-per square and a contact resistivity within a range of about 1.2 milliohms-centemeter² to about 3.5 milliohms-centemeter² (mΩ-cm²).

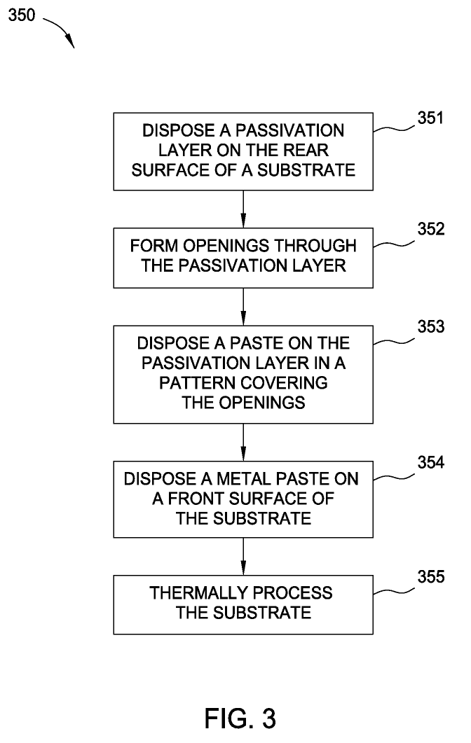

FIG. 3 is a flow diagram 350 illustrating a method of forming a solar cell according to one embodiment of the invention. The flow diagram 350 begins at operation 351, in which a passivation layer is disposed on the non-light receiving side of a substrate, such as a monocrystalline silicon substrate. The passivation layer includes two sub-layers: a first sub-layer of aluminum oxide and a second sub-layer of silicon nitride on the first sub-layer. In one example, the two sub-layers are each deposited via plasma-enhanced chemical vapor deposition (PECVD), and may be deposited in the same or separate processing chambers. In another example, one or more of the two sub-layers are deposited using a physical vapor deposition (PVD) or an atomic layer deposition (ALD) process. The aluminum oxide layer generally has a thickness of about 20 nanometers or more, for example, about 50 nanometers. The aluminum oxide sub-layer may be formed by reacting an aluminum-containing precursor, such as aluminum acetylacetonate or trimethyl aluminum (TMA) with an oxygen containing precursor such as diatomic oxygen (O₂) or ozone (O₃). The silicon nitride layer generally has a thickness within a range of about 50 nanometers to about 150 nanometers, such as about 50 nanometers to about 100 nanometers or 50 nanometers to about 80 nanometers. The silicon nitride sub-layer may be formed by reacting a silicon-containing precursor, such as silane (SiH₄), with a nitrogen containing precursor, such as ammonia (NH₃).

The aluminum oxide layer increases cell efficiency by passivating the rear surface of the solar cell and by facilitating formation of local contacts on the rear surface. However, the aluminum oxide layer is susceptible to degradation by subsequently deposited pastes (for example, pastes described with respect to operation 353). Therefore, the passivation layer also typically includes a silicon nitride layer disposed over the aluminum oxide layer to prevent or reduce contact of subsequently deposited pastes with the aluminum oxide layer.

Subsequent to operation 351, a plurality of openings are formed through the passivation layer. The plurality of openings are scribed through the passivation layer to enable an electrical connection between the substrate and a subsequently deposited back contact utilized for current extraction. The openings are formed using a laser, such as an Nd:YAG laser. In one example, a 200 kHz Q-switch frequency laser may deliver four laser pulses at 355 nanometers and 2.7 watts of energy to form the openings to the desired depth. The openings generally have a diameter within a range of about 20 microns to about 200 microns, and a pitch (e.g., distance between centers of openings) of about 100 microns to about 1000 microns. In one example, the openings may cover about 2% to about 5% of the non-light-receiving surface of the substrate.

In operation 353, a paste, such as an aluminum paste, is disposed on the passivation layer and within the openings in a pattern which includes the openings. The paste is generally deposited by screen printing which can be performed by use of a Softline tool available from Applied Materials Italia S.r.l., which is a division of Applied Materials Inc. of Santa Clara, Calif. Suitable pastes include PV 381 or PV 361 available from DuPont, PASE-1203 available from Monocrystal, Inc., and AL 5120 available from Ferro. It is desirable that the chosen paste suitably adheres to the underlying passivation layer. The pattern is generally a grid pattern including busbars and fingers perpendicular thereto; however, other patterns are also contemplated. The grid pattern of the back contact reduces the amount of aluminum required to form the back contact, particularly when compared to flood-printed back contacts, which cover the entire back surface of the solar cell. The reduction in aluminum, for example, 50% to about 70%, reduces the cost-per-watt generated because the cost of manufacturing the solar cell is reduced. In one example, the cost per watt of a solar cell using a flood printed back contact is about two cents, while the cost per watt of a solar cell using a grid-shaped back contact is about one and one-quarter cents.

Next, in operation 354, a silver paste is disposed on the light-receiving surface of the solar cell to form a front contact grid. The front contact grid may have a shape or pattern similar to the back contact grid, and is likewise deposited by a screen printing process.

In operation 355, the substrate, having the pastes disposed thereon, is thermally processed. Thermal processing of the substrate includes rapidly heating the substrate to a temperature above the eutectic temperature of the materials of the substrate and the back contact (e.g., silicon and aluminum), and then cooling the substrate. The maximum temperature reached during thermal processing, as well as the length of time the substrate is thermally processed, influences the aluminum and silicon concentrations in the local back contacts, as well as the depth of the back surface field near the local contacts. In one example, the substrate may be heated to a temperature of about 800 degrees Celsius in about 90 seconds when processing a silicon substrate having an aluminum-containing paste thereon. During the heating process, aluminum within the aluminum paste becomes fluid and diffuses towards the substrate through the openings. Simultaneously, silicon from the substrate diffuses outwards through the formed openings towards the back contact. At the end of the process the diffused aluminum and silicon solidify into a silicon-aluminum eutectic alloy in the region of the openings to form local back contacts. The formation of the eutectic alloy material in the openings reduces carrier recombination in the region of the openings, due to the diffusion of aluminum into the substrate. In one embodiment, the heating and cooling of the substrate may last about two minutes to four minutes. In another embodiment, the heating and cooling of the substrate may last about 40 seconds to about 50 seconds.

The utilization of a patterned (e.g., grid-shaped) back contact facilitates eutectic alloy formation with a desired composition, thus maximizing the ability of the back surface field to reduce carrier recombination, as well as reducing the contact resistance of the back contact. It is believed that the increased uniformity of eutectic alloy formation in patterned back contacts is, at least, partially due to the reduction in aluminum present in the back contact. In contrast to flood-printed back contacts, patterned back contacts utilize about 50% less material. During thermal processing, silicon becomes the limiting reagent during the eutectic alloy formation process since there is limited exposure of the silicon to the aluminum due to the size of the openings. It is believed that in conventional flood printed back contact processes, where a conventional aluminum paste material is disposed over the rear surface of the substrate, the eutectic alloy material formed during the firing step does not reach the desired aluminum/silicon eutectic composition, due to the over abundance of aluminum present at the interface. However, since approximately 50% less aluminum is present when using patterned back contacts, the aluminum to silicon ratio is reduced, facilitating the formation of an aluminum/silicon eutectic material having a desired composition. Local contacts having the desired composition facilitate formation of a desired back surface field, which reduces charge carrier recombination. Thus, each local contact is formed having the desired eutectic alloy composition. It is to be noted that the amount of silicon available for forming the eutectic composition can be increased by forming larger openings through the passivation layer, thus exposing more of the silicon substrate surface through the passivation layer, which further reduces the aluminum to silicon ratio. Additionally, the amount of silicon available can be increased by including silicon within the printed paste, in increasing the thermal processing time of the substrate to provide a longer diffusion time for the silicon. When adding silicon to the paste utilized for the back contact, silicon may be present within a range from about 0.5% to about 5%, and may include silicon formed into a silicon-aluminum eutectic alloy.

In addition to facilitating local contact formation having a desired composition, the patterned back contact also facilitates uniform composition of each local contact relative to one another. When utilizing flood-printed back contacts, aluminum within the aluminum paste printed on the solar cell has a tendency to diffuse across the back contact during thermal processing and to pool near the center of the back contact. Thus, the concentration of aluminum near the center of the solar cell varies compared to the concentration of aluminum within the paste near the edge of the solar cell. As the solar cell is cooled, and eutectic alloy material forms, the local contacts near the center of the solar cell have a different aluminum concentration than the local contacts near the edge of the solar cell. The difference in composition of local contacts across the solar cell adversely affects back surface field formation and current extraction. The varying concentration of aluminum within the flood-printed contact results in deeper migration of aluminum near the center of the solar cell. Thus, the local contacts near the center of the solar cell extend a greater distance into the substrate compared to local contacts near the edge of the solar cell, thus forming a non-uniform back surface field. However, the use of patterned back contacts overcomes the above-described deficiencies of flood-printed back contacts by reducing the mobility of aluminum through the back contact. The mobility of aluminum is reduced by using a patterned back contact that is deposited over the formed openings in the passivation layer, which have a desired cross-section opening size, rather than a flood-printed back contact. Due to the use of printed back contacts, and the benefits derived therefrom, it has been found that the solar cell efficiency can be increased to about 19%, compared to about 18.2% for flood-printed back contacts.

Flow diagram 350 describes one embodiment of the invention; however, additional embodiments are also contemplated. In another embodiment, it is contemplated that the silicon nitride layer of the passivation layer may be excluded. In such an embodiment, the aluminum oxide layer may be formed to a thickness of about 100 nanometers or more to allow for degradation of the aluminum oxide layer while still providing sufficient passivation qualities. In other embodiments, it is contemplated that additional measures, in cooperation with a patterned back contact, may be utilized to achieve desired local contact compositions. For example, it is contemplated that paste printed on the non-light-receiving surface of the substrate to form the back contact may include silicon or silicon/aluminum eutectic particles having a diameter less than one micron, in addition to aluminum. In yet another embodiment, it is contemplated that a silver-containing paste rather than an aluminum-containing paste may be utilized to form the back contact.

Benefits of the present invention include solar cells with increased efficiency and decreased cost. The increased efficiency and reduced cost is facilitated by a patterned back contact, which reduces the amount of aluminum paste required to manufacture a solar cell, and increases eutectic composition uniformity. Efficiency is further increased due to the reduction of recombination at the back surface of a solar cell which is facilitate by the back surface field. Reduced carrier recombination is promoted by the presence a passivation layer and local contacts of uniform composition. Additionally, cell efficiency is further increased due to reduced contact resistance facilitated by local contacts of desired composition.

While the foregoing is directed to embodiments of the present invention, other and further embodiments of the invention may be devised without departing from the basic scope thereof, and the scope thereof is determined by the claims that follow.

We claim:

1. A solar cell, comprising:
a substrate;
a front contact disposed on a light-receiving surface of the substrate;
a passivation layer disposed on a non-light-receiving surface, the passivation layer having a plurality of openings therethrough and comprising:
a first sub-layer of aluminum oxide; and
a second sub-layer of silicon nitride disposed on the first sub-layer of aluminum oxide;
a back contact disposed on the passivation layer and within the openings, the back contact comprising aluminum and having a grid-like shape; and
a plurality of local contacts formed at the interface of the substrate and the back contact disposed within the openings, the plurality of local contacts comprising a silicon-aluminum eutectic alloy.

2. The solar cell of claim 1, wherein the substrate comprises silicon.

3. The solar cell of claim 2, wherein the openings have a pitch within a range of about 100 microns to about 1000 microns.

4. The solar cell of claim of claim 3, wherein the openings have a diameter within a range of about 20 microns to about 200 microns.

5. The solar cell of claim 1, wherein the back contact covers about 50% or less of the non-light-receiving surface.

6. The solar cell of claim 1, wherein the first sub-layer of aluminum oxide has a thickness of about 20 nanometers or more.

7. The solar cell of claim 6, wherein the second sub-layer of silicon nitride has a thickness within a range of about 20 nanometers to about 100 nanometers.

8. A method of forming a solar cell, comprising:
disposing a passivation layer on a non-light receiving surface of a substrate, the passivation layer comprising:
a first sub-layer of aluminum oxide; and
a second sub-layer of silicon nitride disposed on the first sub-layer of aluminum oxide;
forming a plurality of openings through the passivation layer;
disposing an aluminum paste over the passivation layer in grid-like pattern including the openings; and
heating the substrate and the aluminum paste disposed thereon to a temperature above a silicon-aluminum eutectic point.

9. The method of claim 8, further comprising allowing the substrate to cool after heating the substrate.

10. The method of claim 9, wherein heating and cooling the substrate forms a eutectic composition within the openings of the passivation layer.

11. The method of claim 10, wherein the eutectic composition is an aluminum-silicon eutectic composition.

12. The method of claim 8, wherein the aluminum paste further comprises silicon.

13. The method of claim 8, wherein the aluminum paste further comprises an aluminum-silicon eutectic material.

14. The method of claim 8, wherein heating the substrate and the aluminum paste forms a patterned back contact, and wherein the patterned back contact covers less than about 50% of the surface area of the a non-light-receiving surface of the solar cell.

15. The method of claim 8, wherein the first sub-layer and the second sub-layer are each formed by plasma-enhanced chemical vapor deposition.

16. The method of claim 8, wherein the first sub-layer of aluminum oxide has a thickness of about 20 nanometers or more.

17. The method of claim 8, wherein the openings have a diameter within a range of about 20 microns to about 200 microns, and a pitch of about 100 microns to about 1000 microns.

18. A method of forming a solar cell, comprising:
disposing a passivation layer on a non-light receiving surface of a substrate, the passivation layer comprising:
a first sub-layer of aluminum oxide having a thickness of about 20 nanometers or more; and
a second sub-layer of silicon nitride having a thickness within a range of about 20 nanometers to about 150 nanometers;
forming a plurality of openings through the passivation layer using a laser;
disposing an aluminum paste over the passivation layer in grid-like pattern, the aluminum paste disposed over and within the openings; and
thermally processing the substrate, the thermally processing comprising:
heating the substrate and the aluminum paste thereon to a temperature above a silicon-aluminum eutectic point, and allowing the substrate to cool.

19. The method of claim 18, wherein the aluminum paste comprises silicon.

20. The method of claim 18, wherein the aluminum paste comprises a silicon-aluminum eutectic alloy material.
